(19) United States
(12) Patent Application Publication
(10) Pub. No.: US 2025/0255026 A1
(43) Pub. Date: Aug. 7, 2025

(54) IMAGE SENSOR WITH DEEP TRENCH ISOLATION STRUCTURE AND METHODS THEREOF

(71) Applicant: OMNIVISION TECHNOLOGIES, INC., Santa Clara, CA (US)

(72) Inventors: Qin Wang, San Jose, CA (US); Vincent Venezia, Los Gatos, CA (US)

(21) Appl. No.: 18/953,437

(22) Filed: Nov. 20, 2024

Related U.S. Application Data
(60) Provisional application No. 63/550,397, filed on Feb. 6, 2024.

(51) Int. Cl. H01L 27/146

(52) U.S. Cl. CPC H10F 39/807; H10F 39/024; H10F 39/18; H10F 39/8053; H10F 39/811

(57) ABSTRACT

An image sensor comprising a photodiode, an inter-layer dielectric layer, and a deep trench isolation structure is described. The photodiode is disposed within a semiconductor substrate having a front side and a backside opposite the front side. The inter-layer dielectric layer is disposed over the front side of the semiconductor substrate such that the front side is disposed between the inter-layer dielectric layer and the backside. The deep trench isolation structure is configured to isolate the photodiode from adjacent photodiodes included in the image sensor. The deep trench isolation structure includes a trench disposed within the inter-layer dielectric layer and the semiconductor substrate and a fill material disposed within the trench. The trench extends through the inter-layer dielectric layer and the front side of the semiconductor substrate towards the backside of the semiconductor substrate.

### CROSS-REFERENCE TO RELATED APPLICATION

This application claims the benefit of U.S. Provisional Application No. 63/550,397, filed Feb. 6, 2024, which is hereby incorporated by reference in its entirety.

### TECHNICAL FIELD

The disclosure relates generally to image sensors and in particular, but not exclusively, relates to CMOS image sensors and corresponding fabrication methods.

### BACKGROUND INFORMATION

Image sensors have become ubiquitous and are now widely used in digital cameras, cellular phones, security cameras, as well as in medical, automotive, and other applications. As image sensors are integrated into a broader range of electronic devices, it is desirable to enhance their functionality, performance metrics, and the like in as many ways as possible (e.g., resolution, power consumption, dynamic range) through both device architecture design as well as image acquisition processing. The technology used to manufacture image sensors has continued to advance at a great pace. For example, the demands of higher resolution and lower power consumption have encouraged the further miniaturization and integration of these devices.

A typical complementary metal oxide semiconductor (CMOS) image sensor operates in response to image light from an external scene being incident upon the image sensor. The image sensor includes an array of pixels having photosensitive elements (e.g., photodiodes) that absorb a portion of the incident image light and photogenerate image charge upon absorption of the image light. The image charge photogenerated by the pixels may be measured as analog output image signals on column bitlines that vary as a function of the incident image light. In other words, the amount of image charge photogenerated is proportional to the intensity of the image light, which are read out as analog signals from the column bitlines and converted to digital values to produce digital images (i.e., image data) that represent the external scene.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified. Not all instances of an element are necessarily labeled so as not to clutter the drawings where appropriate. The drawings are not necessarily to scale, emphasis instead being placed upon illustrating the principles being described.

FIG. 1A illustrates a block diagram of an imaging system, in accordance with an embodiment of the disclosure.

FIG. 1B illustrates an example stacked semiconductor device with a deep trench isolation structure corresponding to imaging system illustrated in FIG. 1A, in accordance with embodiments of the disclosure.

FIG. 2A illustrates a front side view of a partial pixel array included in an image sensor with a deep trench isolation structure, in accordance with an embodiment of the disclosure.

FIG. 2B illustrates a backside view of the partial pixel array included in the image sensor of FIG. 2A, in accordance with an embodiment of the disclosure.

FIG. 3A-3B are block diagrams collectively illustrating an example method, for fabrication of an example image sensor with a deep trench isolation structure, in accordance with an embodiment of the disclosure.

FIG. 4A-4M illustrate cross-sectional diagrams for fabrication states associated with the method illustrated in FIG. 3A-3B, in accordance with an embodiment of the disclosure.

FIG. 5A-5E represent fabrication states for forming an image sensor including a deep trench isolation structure with a dielectric cap structure to protect the deep trench isolation structure from being damaged during backside thinning or etching, in accordance with an embodiment of the disclosure.

FIG. 6A-6C illustrate an embodiment in which the fill material of the deep trench isolation structure is coupled to receive a biasing voltage to provide enhanced passivation, in accordance with an embodiment of the disclosure.

### DETAILED DESCRIPTION

Embodiments of an apparatus, system, and method each related to an image sensor with a deep trench isolation structure are described herein. In the following description, numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

Further, it will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.). Additionally, it will be understood that when an element or layer is referred to as being “formed on,” another element or layer, it can be directly or indirectly formed on the other element or layer. That is, for example, intervening elements or layers may be present. In contrast, when an element or layer is referred to as being “directly formed on,” to another element, there are no intervening elements or layers present.

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

The term “have”, “may have”, “include”, “may include” or “comprise” used herein indicates the existence of a corresponding feature (e.g., a number, a function, an operation, or an element) and does not exclude the existence of an additional feature. The term “A or B”, “at least one of A and/or B”, or “one or more of A and/or B” may include all possible combinations of items listed together. For example, the term “A or B”, “at least one of A and B”, or “at least one of A or B” may indicate all the cases of (1) including at least one A, (2) including at least one B, and (3) including at least one A and at least one B.

The term “pixel cell” or “pixel group” may be used to indicate a unit pixel structure that includes a plurality of photodiodes (e.g., two photodiodes, four photodiodes, 8 photodiodes, 16 photodiodes or more) that share a common component of the circuitry or a common optical element (e.g., common or shared circuitry such as a floating diffusion region, common or shared optical element such as a shared color filter or microlens, or the like) in the pixel cell. For example, the plurality of photodiodes included in a pixel cell may be arranged to be underneath a single color filter and/or a single microlens. The number of subpixels in each pixel cell may vary depending on implementations of the disclosed technology. In one example, a pixel cell may refer to a unit pixel that includes four photodiodes. In another example, a pixel cell may refer to a unit pixel that includes two photodiodes. In still another example, a pixel cell may refer to a unit pixel that includes eight photodiodes. In another example, a pixel cell may refer to a unit pixel that includes sixteen photodiodes.

The term “configured (or set) to” may be interchangeably used with the term, for example, “suitable for”, “having the capacity to”, “designed to”, “adapted to”, “made to”, or “capable of”. The term “configured (or set) to” may not necessarily have the meaning of “specifically designed to”. In some cases, the term “device configured to” may indicate that the device “may perform” together with other devices or components. For example, the term “processor configured (or set) to perform A, B, and C” may represent a dedicated processor (e.g., an embedded processor) for performing a corresponding operation, or a generic-purpose processor (e.g., a CPU or an application processor) for executing at least one item of software or program stored in a memory device to perform a corresponding operation.

The term “vertical” refers to a direction that is perpendicular to a surface of a substrate or material layer. The term “high-κ material” herein refers to a material having a relative dielectric constant that is greater than 3.9. In some embodiments, the term “high-κ material” may also refer to a material having a relative dielectric constant that is greater than a relative dielectric constant of the silicon dioxide (SiO₂). The term “p-type” defines a structure, layer, and/or region in a substrate material layer (e.g., semiconductor substrate or epitaxial layer) as being doped with a p-type dopant, such as boron. The term “n-type” defines a structure, layer, and/or region in a substrate material layer (e.g., semiconductor substrate or epitaxial layer) as being doped with an n-type dopant, such as phosphorus and/or arsenic.

In some embodiments, the term “about” and the term “substantially” can refer to a value of a given quantity or manufacturing parameters that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings of the present disclosure.

Deep trench isolation structures (e.g., trench structures filled with a dielectric material) are employed in an image sensor to provide electrical and/or optical isolation between adjacent pixels in a pixel array. The effectiveness of deep trench isolation structures depends on the associated trench depth, where deeper isolation depth exhibits improved electrical and/or optical isolation between pixels that may reduce or prevent pixel-pixel electron leakage (e.g., blooming) and optical crosstalk. In some embodiments of the disclosure, an image sensor with a full deep trench isolation structure is described by forming a trench that extends a full depth or thickness of the semiconductor substrate (e.g., silicon substrate, wafer substrate, or epitaxial layer) having photodiodes formed therein. It is appreciated that full deep trench isolation structures generally provide more effective isolation relative to partial deep trench isolation structures that do not extend entirely through a semiconductor substrate but may be simpler or cheaper to fabricate. It is appreciated that the trenches of full deep trench isolation structures may be referred to as through-trenches since each trench extends fully or entirely through the semiconductor substrate rather than terminating at a point within the semiconductor substrate. It is appreciated that the thickness of the semiconductor substrate may change during manufacturing of the image sensor (e.g., at least a portion of the semiconductor substrate may be removed, for example from the backside thereof or the semiconductor substrate may otherwise be thinned) such that during one or more intermediate stages of manufacture the deep trench isolation structure may not extend entirely through the semiconductor substrate. However, in some embodiments, the deep trench isolation structure extends entirely through a final thickness of the semiconductor substrate (e.g., a thickness of the semiconductor substrate after completion of the image sensor manufacturing process).

It is appreciated that a deep trench isolation structure may be referred to by their manner of fabrication, which includes backside deep trench isolation structures and front side deep trench isolation structures.

Backside deep trench isolation structures are formed by etching through a backside (e.g., an illuminated or light-receiving side) of a semiconductor substrate. However, backside deep trench isolation structures may be limited in processing since they are typically formed after front side elements (e.g., transistors, contacts, metallization layer structure) are formed, meaning high temperature processes may not be viable (e.g., high temperature annealing such as hydrogen annealing) that can be utilized to repair etching damage (e.g., plasma damages) to improve dark current noises. Additionally, it may be difficult to align the backside deep trench isolation structures with front side elements and also difficult to form a full or through substrate isolation structure due to possible damage to front side elements. The challenges of backside deep trench isolation structures may be exacerbated as pixel size continues to shrink resulting in a deep trench isolation structure that has reduced electrical and/or optical isolation performance or impacts full well capacity of nearby photodiodes.

Front side deep trench isolation structures are formed by etching through a front side (e.g., non-illuminated side) of a semiconductor substrate and may be formed on the front side of a semiconductor substrate after the formation of shallow trench isolation structures (e.g., formed on the backside of the semiconductor substrate). Fabrication of front side deep trench isolation structures may be simplified since the tolerance for trench depth is relaxed relative to the corresponding backside processes. Additionally, trenches formed deeper within the semiconductor substrate are not at risk of damaging front side elements of the image sensor (e.g., since the front side deep trench isolation structure is formed before the front side elements). Using a high-κ material for surface passivation has been found to limit the use of high thermal processes (such as an annealing process for dopant activation and silicon damage recovery) as high temperature (e.g., process with applied temperature greater than 700° C.) could damage or degrade the high-κ material and reduce the surface passivation effect provided by the high-κ material (e.g., reduce number of negative charges). Additionally, the process of forming a trench by plasma etching may induce defects on a surface of the semiconductor substrate surrounding the trench resulting in charge trap sites. As such, insufficient passivation of the defects could lead to increased dark current and noise during operation of the image sensor.

Embodiments described herein illustrate various image sensors that may have full deep trench isolation structure fabricated from the front side of the semiconductor substrate that overcomes the aforementioned shortcomings of both front side type full deep trench isolation structure formation and backside type full deep trench isolation formation. In embodiments of the disclosure, a plurality of front side deep trenches may be formed by etching (e.g., dry and/or wet etching processes) through an inter-layer dielectric layer formed on a front side of the semiconductor substrate enclosing at least one front side circuitry element with a high temperature process (e.g. high temperature annealing) applied thereafter. Subsequently, a liner material can be formed lining the plurality of front side deep trenches. Afterwards, a first high-κ passivation layer is deposited into the plurality of front side deep trenches through openings formed on the inter-layer dielectric layer to form a continuous layer that coats the liner material and extends a full depth of the plurality of front side deep trenches. After formation of the first high-passivation layer, the plurality of front side trenches may be filled with a fill material (e.g., a dielectric or conductive material) to form a full front side deep trench isolation structure that is enclosed by a capping layer (e.g., an oxide-based material). Subsequently, contact and metallization layers proximate to the capping layer may be formed. In embodiments of the disclosure, the semiconductor substrate is thinned or otherwise processed to remove at least a portion of substrate material included in the semiconductor substrate from the backside to expose the deep trench isolation structure. Subsequently a second high-κ passivation layer covering the backside of the semiconductor substrate may be formed. After the semiconductor substrate is thinned, the deep trench isolation trench has a trench depth that is substantially equal to a substrate thickness of the thinned semiconductor substrate (i.e., the deep trench isolation trench structure extends entirely through a final thickness of the semiconductor substrate). In such embodiments, the final thickness of the semiconductor substrate may referred to as the thickness of the semiconductor substrate after the thinning process, which may also corresponds to the resulting thickness after completion of the image sensor manufacturing process. Subsequently, optical elements of the image sensor (e.g., color filters, metal grid structure, array of microlenses, and the like) may then be formed on backside of the semiconductor substrate (e.g., formed on the second high-κ passivation layer and/or over one or more additional layers such as oxide-based layers).

It is appreciated that forming the trenches for the deep trench isolation structure from front side (e.g., front side trenches) of the semiconductor substrate after formation (e.g., deposition or growth) of the inter-layer dielectric layer is advantageous because the front side trenches may be easily aligned with pixel elements and further extend sufficiently deep to improve isolation of photodiode regions for all pixels of the image sensor. Further, high temperature processes (e.g., hydrogen annealing) can be applied to cure defects (e.g., dangling bonds) caused by etching the trenches, which improves white pixel and dark current performance.

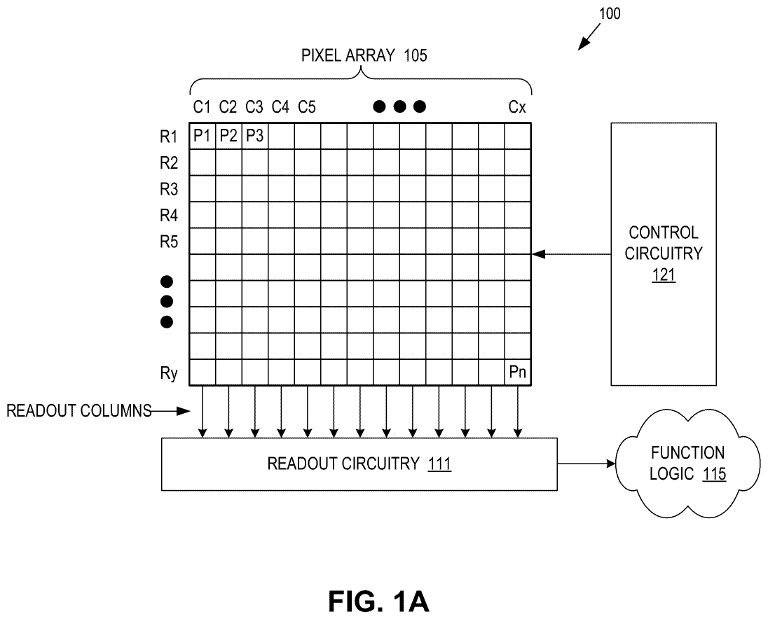

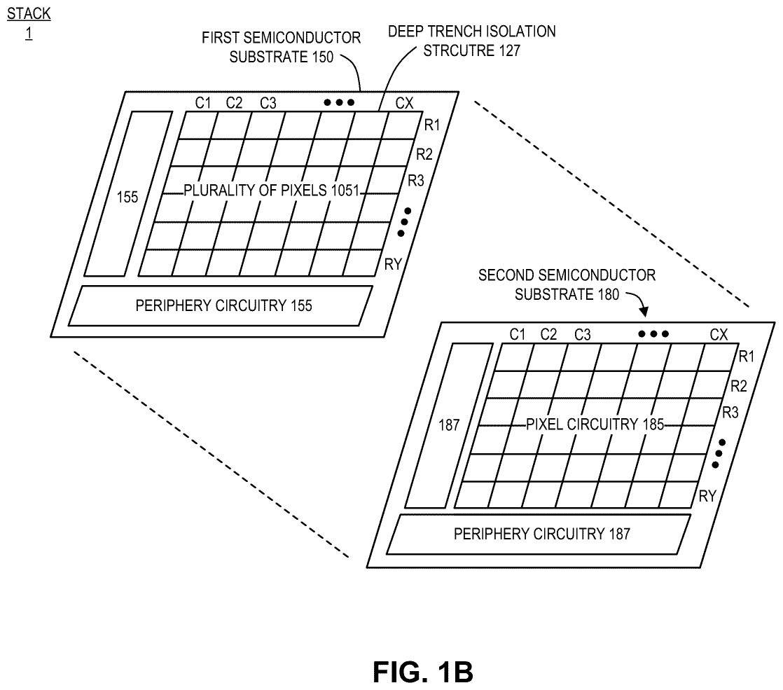

FIG. 1A illustrates a block diagram of an imaging system 100, in accordance with an embodiment of the disclosure. Imaging system 100 includes pixel array 105, control circuitry 121, readout circuitry 111, and function logic 115. In one embodiment, pixel array 105 is an array of photodiodes or image sensor pixels (e.g., pixels P1, P2, . . . , Pn) that have individual photodiodes or pixels isolation from adjacent photodiodes or pixels by a deep trench isolation structure. As illustrated, image sensor pixels are arranged into rows (e.g., rows R1 to Ry) and columns (e.g., column C1 to Cx) to acquire image data of a person, place, object, etc., which can then be used to render an image or video representative of the person, place, object, etc. However, it is appreciated in other embodiments, photodiodes or image sensor pixels do not have to be arranged into rows and columns and may take other configurations.

In one embodiment, each of the image sensor pixels or photodiodes are separated and isolated from each other by a full front side deep trench isolation structure. In various example embodiments, the full deep trench isolation structure may be arranged in a trench-grid form to provide optical and/or electrical isolation between adjacent photodiodes or pixels in pixel array 105. In some embodiments, image sensor pixels or photodiodes are grouped into a plurality of pixel cells that form the pixel array 105. It is appreciated that each of the plurality of pixel cells may include any number of photodiodes or image sensor pixels (e.g., one, two, four, eight, or more photodiodes or image sensor pixels per pixel cell). In most embodiments, the number of photodiodes or image sensor pixels per pixel cell included in the plurality of pixel cells is uniform.

In the various embodiments, readout circuitry 111 may be configured to read out image signals (e.g., image charge photogenerated in response to incident light) at different conversion gains through column bitlines (e.g., readout columns). In various embodiments, readout circuitry 111 may include one or more current sources, routing circuitry, and comparators that may be included in analog to digital converters or otherwise.

In one embodiment, after each image sensor pixel or photodiode included in pixel array 105 has acquired its image charge, the image charge is readout as image data by readout circuitry 111 and then transferred to function logic 115. In various embodiments, readout circuitry 111 may include amplification circuitry, analog-to-digital (ADC) conversion circuitry, or otherwise. Function logic 115 may simply store the image data or even manipulate the image data by applying post image effects (e.g., autofocus, crop, rotate, remove red eye, adjust brightness, adjust contrast, or otherwise). In the same or another embodiment, readout circuitry 111 may readout a row of image data at a time along readout column lines (illustrated) or may readout the image data using a variety of other techniques (not illustrated), such as a serial readout or a full parallel readout of all image pixels simultaneously. In one embodiment, control circuitry 121 is coupled to pixel array 105 to control operation of the plurality of image sensor pixels in pixel array 105. For example, control circuitry 121 may generate a shutter signal for controlling image acquisition. In some embodiments, control circuitry 121 may be configured to generate drive signals (e.g., transfer signals, reset signals, and row-select signals) for controlling the operation of pixel circuitries associated with image sensor pixels in pixel array 105.

It is appreciated that imaging system 100 may be included in an image sensor that can be incorporated into a digital camera, cell phone, laptop computer, automobile, surveillance camera, or the like. Additionally, imaging system 100 may be coupled to other pieces of hardware such as a processor (general purpose or otherwise), memory elements, output (USB port, wireless transmitter, HDMI port, etc.), lighting/flash, electrical input (keyboard, touch display, track pad, mouse, microphone, etc.), and/or display. Other pieces of hardware may deliver instructions to imaging system 100, extract image data from imaging system 100, or manipulate image data supplied by imaging system 100.

While the block diagram illustrated in FIG. 1A shows pixel array 105, readout circuitry 111, function logic 115, and control circuitry 121 as distinct and separate elements from the pixel array 105, it should be appreciated that this is not necessarily the case as such features may be combined or otherwise incorporated with the pixel array directly (e.g., within and/or between individual pixels, in the form of stacked substrates, or otherwise). For example, the readout circuitry 111 may include one or more transistors (e.g., associated with 3T, 4T, 5T, or other pixel architectures for reading out image charge from individual pixels) that have elements disposed between segments of individual photodiodes in accordance with embodiments of the present disclosure. Furthermore, the imaging system 100 may include features not explicitly illustrated or discussed but known by one of ordinary skill in the art such as color filters, microlenses, a metal grid structure, a composite metal-dielectric grid, or combinations thereof. Additionally, it is appreciated that imaging system 100 may be included in an image sensor that is fabricable by conventional CMOS manufacturing techniques known by one of ordinary skill in the art, which may include, but is not limited to, photolithography, chemical vapor deposition, physical vapor deposition, atomic layer deposition, ion implantation or diffusion, thermal oxidation, reactive ion etching, wet chemical etching, chemical mechanical polishing, and the like.

FIG. 1B illustrates an example stacked semiconductor device configuration STACK 1 corresponding to imaging system 100, in accordance with embodiments of the disclosure. The imaging system 100 corresponds to an image sensor for imaging an external scene. The imaging system 100 includes a first semiconductor substrate 150 and a second semiconductor substrate 180, each of which may correspond to a part of or an entirety of a semiconductor wafer or die in accordance with embodiments of the disclosure. The first semiconductor substrate 150 includes a plurality of pixels 1051 forming the pixel array 105, deep trench isolation structure 127, and periphery circuitry 155 formed thereon or therein. In the illustrated embodiment, each pixel included in plurality of pixels 1051 includes one photodiode that is isolated from other photodiodes included in the plurality of pixels 1051 by deep trench isolation structure 127. In other words, deep trench isolation structure 127 forms a grid structure defining pixel regions of the first semiconductor substrate 150 that components of a given pixel (e.g., photodiode, source/drain regions or electrodes, etc.) of the plurality of pixels 1051 are disposed therein. That is, each of the pixels included in plurality of pixels 1051 are separated and isolated from each other pixel by a corresponding segment of the deep trench isolation structure 127 to effectively reduce electrical and/or optical crosstalk.

In some embodiments, pixels included in the plurality of pixel 1051 are grouped together to form a plurality of pixel cells having a regular arrangement (e.g., a two-by-two arrangement of four photodiodes or image sensor pixels, a two-by-three arrangement of six photodiodes or image sensor pixels, a two-by-four arrangement of eight photodiodes or image sensor pixels, a four-by-four arrangement of sixteen photodiodes or image sensor pixels, or otherwise). In some embodiments, an individual pixel cell formed by the plurality of pixels 1051 may correspond to a minimal repeating unit of the first semiconductor substrate 150. In some embodiments, the pixel circuitry 185 of the second semiconductor substrate 180 is arranged based on a corresponding arrangement of the plurality of pixels 1051. For example, in some embodiments, individual pixel included in the plurality of pixel 1051 of the first semiconductor substrate 150 may be respectively coupled to individual groups of components included in the pixel circuitry 185 of the second semiconductor substrate 180 on a per-pixel or per-pixel cell basis, which may result in an arrangement of the pixel circuitry 155 being regular and/or repeating (e.g., in rows and columns as illustrated).

In some embodiments, individual pixels included in the plurality of pixel 1051 may be grouped together as pixel cells having two or more photodiodes or image sensor pixels that share a common color filter or otherwise are optically aligned with color filters having a common spectral photoresponse (e.g., a group of four adjacent photodiodes or image sensor pixels included in plurality of pixels 1051 arranged in a two-by-two pattern may be optically aligned with a first color filter to form a first pixel cell included in the plurality of pixels 1051). In other embodiments, adjacent pixels included in the plurality of pixels 1051 do not share a common color filter or microlens (e.g., color filters of adjacent pixels included in the plurality of pixels 1051 have different spectral photoresponses). In some embodiments, groups of pixels included in the plurality of pixels 1051 that form a pixel cell may share a common microlens or otherwise be optically aligned with a single microlens.

In the illustrated embodiment, the second semiconductor substrate 180 includes pixel circuitry 185 and periphery circuitry 187 formed or otherwise disposed thereon. In some embodiments, the pixel circuitry 185 may be segmented into groups of components that are associated with respective pixels included in the plurality of pixels 1051 or pixel cells formed by groups of the plurality of pixels 1051 to facilitate operation and/or readout for the imaging system 100, which may be physically aligned or otherwise overlap across substrates (e.g., components for readout circuitry for a given pixel or pixel cell included in the plurality of pixels 1051 located in or on the second semiconductor substrate 180 may vertically overlap with the given pixel or pixel cell located in or on the first semiconductor substrate 150).

In the illustrated embodiment, the imaging system 100 is a complementary metal-oxide semiconductor (CMOS) image sensor formed, at least in part, by the first semiconductor substrate 150 (e.g., a first die) and the second semiconductor substrate 180 (e.g., a second die) that are stacked and coupled together (e.g., electrically and physically) in a stacked chip scheme achieved, at least in part, via hybrid bonding on a per-pixel or per-pixel cell basis. It is appreciated that other types of bonding (e.g., oxide bonding, metal bonding), silicon connections (e.g., through silicon vias), other suitable circuit coupling technologies, or combinations thereof may also be utilized in combination with hybrid bonding to form the imaging system 100. It is appreciated that while only the first semiconductor substrate 150 and the second semiconductor substrate 180 are illustrated in FIG. 1B, the stacked chip scheme of the imaging system 100 may include additional substrates (e.g., one or more additional substrates, dies, or chips different from the first semiconductor substrate 150 and the second semiconductor substrate 180) that may be integrated into the stacked chip scheme of the imaging system 100.

The STACK 1 configuration illustrated in FIG. 1B, distributes components of the imaging system 100 across multiple substrates. Specifically, the first semiconductor substrate 150 includes photosensitive elements (e.g., a plurality of photodiodes such as pinned photodiodes or the like to form image sensor pixels) included in the plurality of pixels 1051 while the second semiconductor substrate 180 includes pixel circuitry 185 associated with the plurality of pixel 1051 (e.g., any one of or a combination of pixel transistors such as reset transistors, source-follower transistors, row select transistors, and so on, analog to digital circuitry, signal processing circuitry, or other circuitry to facilitate imaging an external scene with the pixels included in the plurality of pixel 1051). Put in another way, the second semiconductor substrate 180 offloads at least part of the circuitry associated with the plurality of pixel 1051 from the first semiconductor substrate 150, which advantageously provides additional space on the first semiconductor substrate 150 (e.g., to reduce pixel pitch, increase photodiode sensing area relative to total pixel area, and so on).

In some embodiments, the plurality of pixels 1051 may be coupled to the pixel circuitry 185 through a plurality of connection pads embedded in an insulating medium or matrix. It is appreciated that the plurality of connection pads may be positioned at a bonding interface disposed between the first semiconductor substrate 150 and the second semiconductor substrate 180. One or more connection vias, metal wires, lines, or traces, contacts, or combinations thereof (e.g., interconnects) may further electrically couple the plurality of connection pads to various components (e.g., floating diffusion regions) located in or on the first semiconductor substrate 150 and/or the second semiconductor substrate 180. In some embodiments, the plurality of pixels 1051 may be coupled to the pixel circuitry 185 through a plurality of through silicon vias disposed within a periphery region of the first semiconductor substrate 150 (e.g., periphery circuitry 155). In some embodiments, the space saved on the first semiconductor substrate 150 by offloading circuitry to the second semiconductor substrate 180 (or other subsequent substrates in the stacked chip scheme) may be repurposed to increase the size of individual photodiodes included in each of the pixels of the plurality of pixel 1051 to allow for increased pixel size, density, sensitivity, combinations thereof, or the like.

In some embodiments, the first semiconductor substrate 150 and the second semiconductor substrate 180 include various analog and/or digital support circuitries for the imaging system 100 that may respectively correspond to periphery circuitry 155 and the periphery circuitry 187. In some embodiments, support circuitry that may be included in the periphery circuitry 155 and/or the periphery circuitry 187 may include, but is not limited to, row and column decoders and drivers, analog signal processing chains, digital imaging processing blocks, memory, timing and control circuits, input/output interfaces, a vertical scanner, sample and hold circuitry, amplifiers, analog-to-digital converter circuitry, and any other embodiments of logic and/or circuitry that is appropriate for the function of the imaging system 100.

It is appreciated that the views presented in FIG. 1A-1B may omit certain elements of the imaging system 100 to avoid obscuring details of the disclosure. In other words, not all elements of the imaging system 100 may be labeled, illustrated, or otherwise shown within FIG. 1A-1B or other figures throughout the disclosure. It is further appreciated that in some embodiments, the imaging system 100 may not necessarily include all elements shown.

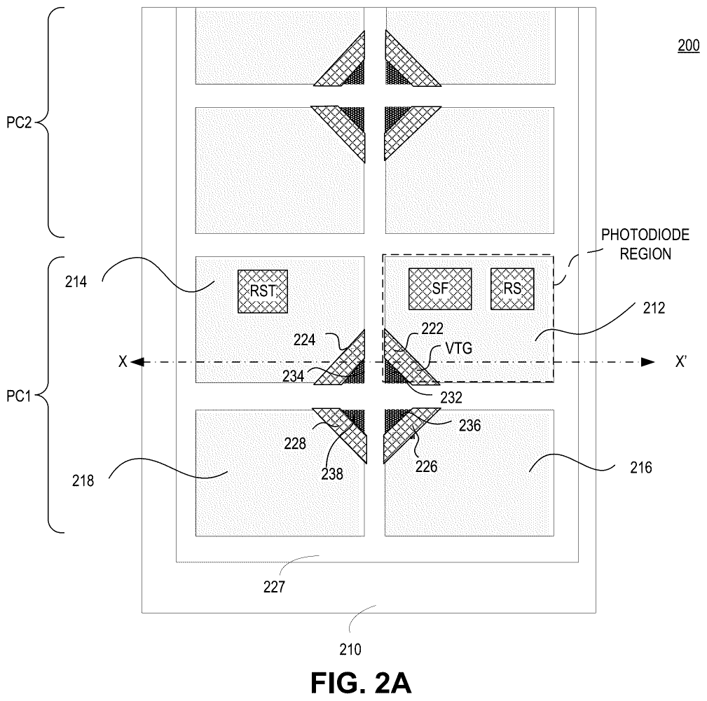

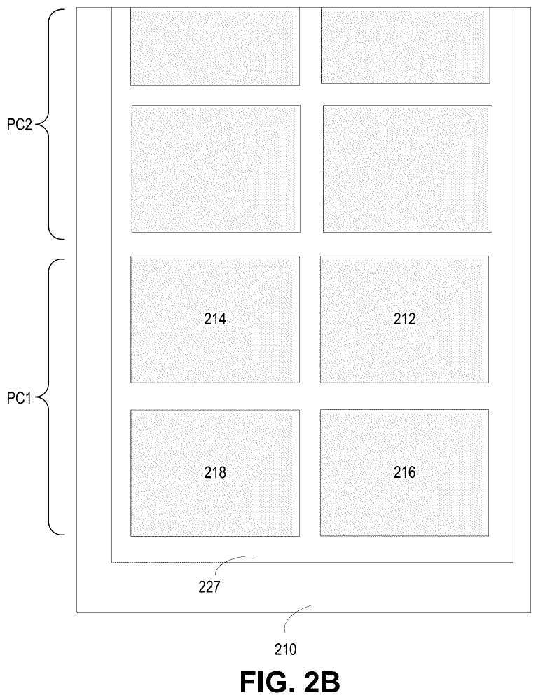

FIG. 2A illustrates a front side view (e.g., non-illuminated side) of a partial pixel array included in an image sensor 200 in accordance with an embodiment of the disclosure. It is appreciated that image sensor 200 is one possible implementation of the image sensor 100 illustrated in FIG. 1A. The example pixel layout of FIG. 2A may be one possible implementation of pixels included in the plurality of pixels 1051 that collectively form a pixel array of FIG. 1B and/or the pixel array 105 of FIG. 1A when viewed from a front side (e.g., non-illuminated side) of a semiconductor substrate 210. It is appreciated the semiconductor substrate 210 may correspond to the first semiconductor substrate 150 illustrated in FIG. 1B. In some embodiments, semiconductor substrate 210 may correspond to a part of or an entirety of a semiconductor wafer (e.g., a silicon wafer, one or more epitaxial layers of the aforementioned materials, or a bulk substrate thereof). The illustrated embodiment of FIG. 2A shows pixel cell PC1, which may be representative of each pixel cell included in the pixel array of the image sensor 200 (e.g., pixel cell PC2). As illustrated, the pixel cell PC1 includes photodiodes 212, 214, 216, 218 arranged in a two-by-two pattern, a plurality of transfer gates 222, 224, 226, 228, a plurality of floating diffusion regions 232, 234, 236, 238, and deep trench isolation structure 227, each formed in or on semiconductor substrate 210. It is appreciated deep trench isolation structure 227 may correspond to deep trench isolation structure 127 illustrated in FIG. 1B.

In some embodiments, the deep trench isolation structure 227 is configured to form a grid defining individual pixel regions. In such an embodiment, the deep trench isolation structure 227 laterally surrounds or encloses pixel regions of the semiconductor substrate 210. It is appreciated that each of photodiodes 212, 214, 216, and 218 are disposed within a respective one of the enclosed pixel regions such that each of photodiodes 212, 214, 216, and 218 is individually isolated. In addition to providing individual isolation for photodiodes, the grid structure of the deep trench isolation structure 227 may also provide separation between different pixel cells (e.g., pixel cell PC1 is isolated from pixel cell PC2 by deep trench isolation structure 227). In some embodiments, the deep trench isolation structure 227 provides electrical, optical, and/or physical isolation between individual pixel regions and individual pixel cells. In the same or other embodiments, the deep trench isolation structure 227 defines the area or regions (i.e., enclosed pixel regions) for individual pixels and/or pixel cells (e.g., PC1 and PC2) and further defines the area or regions (e.g., shaded photodiode regions) for each of the individual photodiodes 212, 214, 216, and 218. Put in another way, the deep trench isolation structure separates and isolates each of plurality of photodiodes 212, 214, 216, and 218 and further provides electrical and/or optical isolation between the plurality of photodiodes 212, 214, 216, and 218.

The plurality of floating diffusion regions 232, 234, 236, 238 and the plurality of transfer gates 222, 224, 226, 228 are disposed in or on a corresponding enclosed pixel region defined by deep trench isolation structure 227. In some embodiments, the plurality of floating diffusion regions 232, 234, 236, 238 and the plurality of transfer gates 222, 224, 226, 228 are disposed in or on (e.g., when viewed from the plan view provided by FIG. 2A) a respective one of photodiodes 212, 214, 216, and 218. In some embodiments, floating diffusion region 232 is disposed within a photodiode region of the photodiode 212 and transfer gate 222 is disposed in or on the photodiode region of the photodiode 212 and configured to selectively couple the photodiode 212 to floating diffusion region 232. In some embodiments, floating diffusion region 234 is disposed within a photodiode region of the photodiode 214 and transfer gate 224 is disposed in or on the photodiode region of the photodiode 214 and configured to selectively couple the photodiode 214 to floating diffusion region 234. In some embodiments, floating diffusion region 236 is disposed within a photodiode region of the photodiode 216 and transfer gate 226 is disposed in or on the photodiode region of the photodiode 216 and configured to selectively couple the photodiode 216 to floating diffusion region 236. In some embodiments, floating diffusion region 238 is disposed within a photodiode region of the photodiode 218 and transfer gate 228 is disposed in or on the photodiode region of the photodiode 218 and configured to selectively couple the photodiode 218 to floating diffusion region 238.

In some embodiments, each of the plurality of transfer gates 222, 224, 226, and 228 includes a planar gate portion and a vertical gate portion extending from the planar gate portion (e.g., collectively referred to as a vertical transfer gate or VTG) that is disposed proximate to a photodiode doped region (e.g., n-type photodiode doped region) of each respective photodiode to facilitate charge transfer between each photodiode and a corresponding floating diffusion region. In some embodiments, the plurality of floating diffusion regions 232, 234, 236, 238 and the photodiode doped region included in each of the plurality of photodiodes 212, 214, 216, 218 may be of a same conductivity type (e.g., n-type or p-type) that is opposite of a conductive type (p-type or n-type) of the semiconductor substrate 210.

In some embodiments, the plurality of floating diffusion regions 232, 234, 236, 238 may be coupled together (e.g. via a polysilicon connector or metal interconnect in metal layers) for charge binning operation. In such an embodiment, one or more transistors (e.g., source-follower transistor, reset transistor, or row select transistor) that are shared by the plurality of photodiodes 212, 214, 216, 218 may be formed in or on respective photodiode regions of the plurality of photodiodes 212, 214, 216, 218. The one or more transistors (e.g., source-follower transistor, reset transistor, or row select transistor) may have portions (e.g., source and drain regions) formed between a respective photodiode region of a photodiode and an inter-layer dielectric layer (not illustrated in FIG. 2A) that encapsulates the plurality of transfer gates 222, 224, 226, 228 and respective gates of the one or more transistors. In the illustrated embodiment, components of source-follower transistor (e.g., gate SF) and row select transistor (e.g., gate RS) may be formed in or on the photodiode region of the photodiode 212. For example, source and drain regions of source-follower transistor and row select transistor may be formed in or on the semiconductor substrate 210 between the inter-layer dielectric layer (not illustrated in FIG. 2A) and the photodiode region of the photodiode 212, and source follower gate and row select gate may be formed proximate to a surface (e.g., front surface) of the semiconductor substrate 210. In the illustrated embodiment, components for the reset transistor (e.g., gate RST) may be formed in or on the photodiode region of the photodiode 214. For example, source and drain regions of reset transistor RST may be formed on the semiconductor substrate 210 between the inter-layer dielectric layer (not illustrated in FIG. 2A) and the photodiode region of the photodiode 214 and reset gate may be formed proximate to the surface (e.g., front surface) of the semiconductor substrate 210.

In some embodiments, the source-follower transistor has a gate SF coupled to the plurality of floating diffusion region 232, 234, 236, 238 (e.g., via a polysilicon layer or metal layer). In some embodiments, the row select transistor is coupled to the source-follower transistor such that the source-follower transistor and the row select transistor are coupled between a power line AVDD (not illustrated) and a bitline (not illustrated) to output an image signal from the corresponding pixel cell in response to a row select control signal RS_{SIG} applied to gate RS and the amount of charge at the gate SF of the source-follower transistor. In the same or other embodiments, the reset transistor is coupled between a reset voltage source Pix_{VDD} and the plurality of floating diffusion regions 232, 234, 236, 238 and the reset transistor is coupled to be controlled in response to a reset control signal RST_{SIG} applied to gate RST.

FIG. 2B illustrates a backside view (e.g., an illuminated side) of the partial pixel array included in an image sensor 200 of FIG. 2A, in accordance with an embodiment of the disclosure. As illustrated, deep trench isolation structure 227 extends entirely through the semiconductor substrate 210 to provide complete depthwise isolation for enclosed pixel regions of the semiconductor substrate 210. The semiconductor substrate 210 although illustrated in a planer view may be an example fabricated substrate structure in the image sensor 200. Accordingly, deep trench isolation structure 227 is referred to as a full deep trench isolation structure that is formed in the semiconductor substrate 210 and has a depth that is substantially equal to a final thickness (e.g., from 2.5 μm to 7 μm) of the semiconductor substrate 210. In other words, deep trench isolation structure 227 is a through substrate structure configured to provide complete isolation between adjacent photodiodes (e.g., photodiodes 212, 214, 216, and 218 are completely isolated from one another by deep trench isolation structure 227 both laterally and vertically with respect to semiconductor substrate 210) and between adjacent pixel cells (e.g., pixel cells PC1 and PC2 are completely isolated from one another by deep trench isolation structure 227 both laterally and vertically with respect to semiconductor substrate 210).

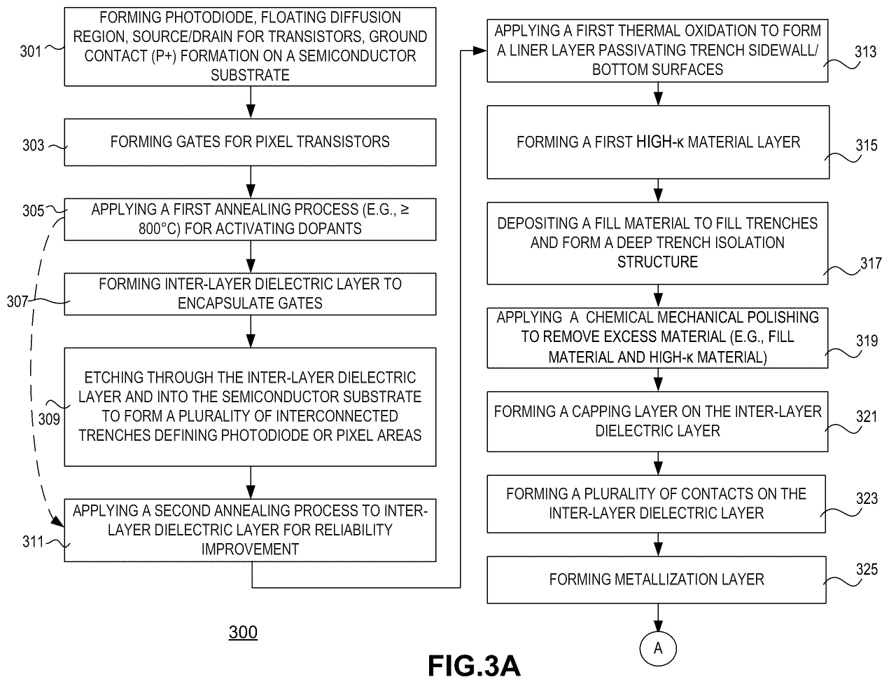

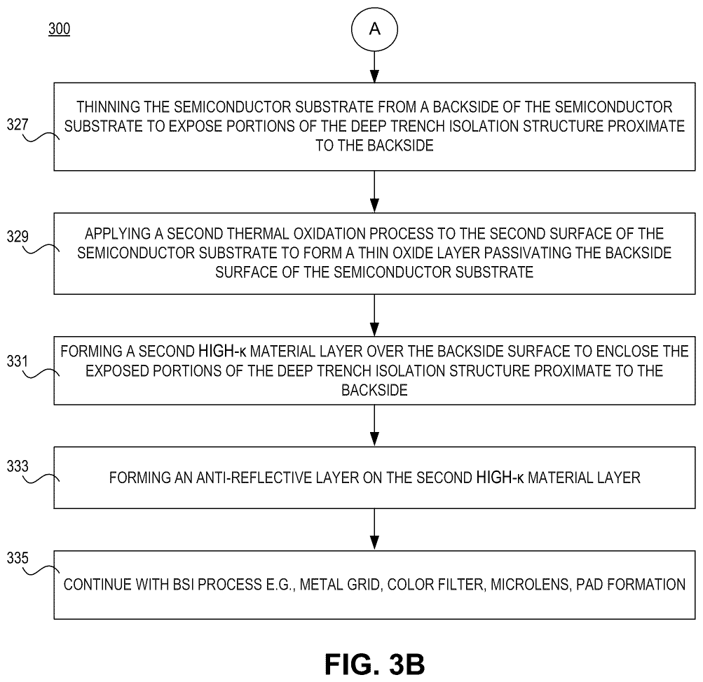

FIG. 3A and FIG. 3B are block diagrams collectively illustrating an example method 300, for fabrication of an example image sensor with a deep trench isolation structure, in accordance with an embodiment of the disclosure. The order in which some or all of the process blocks appear in method 300, which includes process blocks 301, 303, 305, 307, 398, 311, 313, 315, 317, 319, 321, 323, 327, 329, 331, 333, and 335 should not be deemed limiting. Rather, one of ordinary skill in the art having the benefit of the present disclosure will understand that some of the process blocks of method 300 may be executed in a variety of orders not illustrated, or even in parallel. Although method 300 is described in connection with forming an image sensor, it is appreciated that the deep trench isolation structure may also be included in other semiconductor devices.

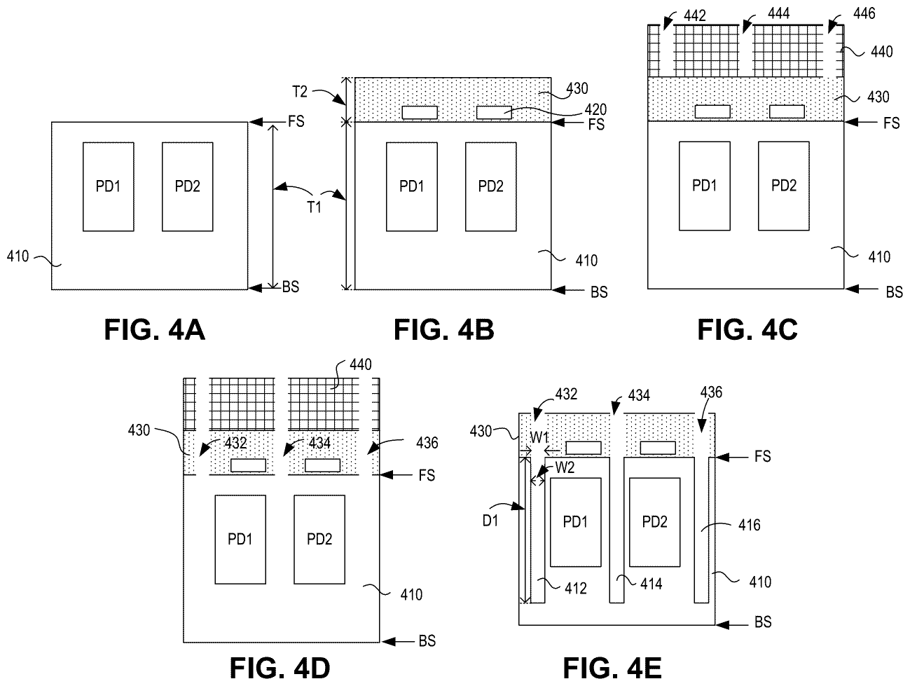

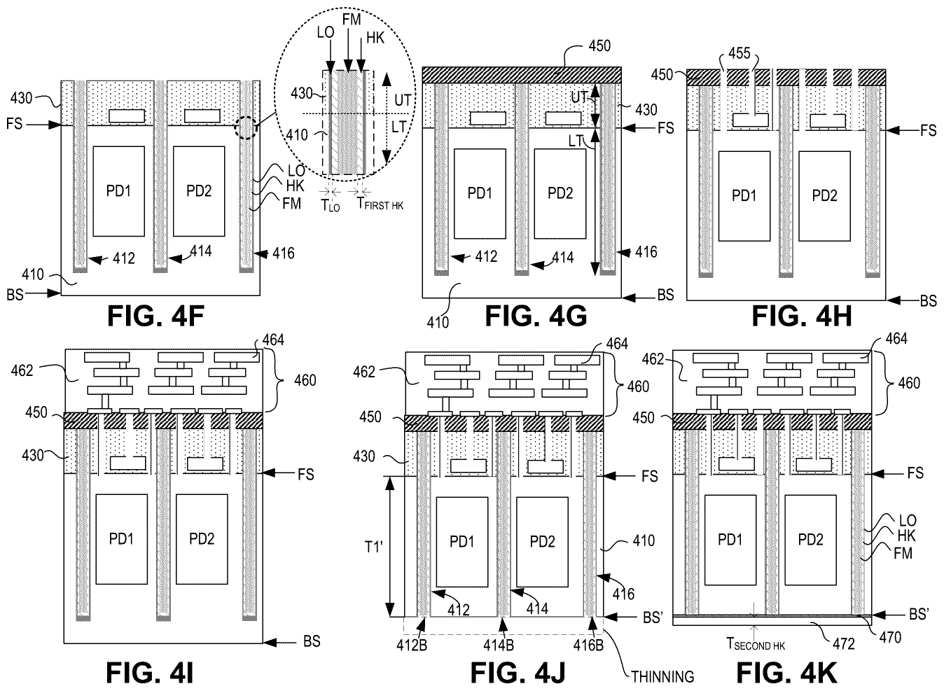

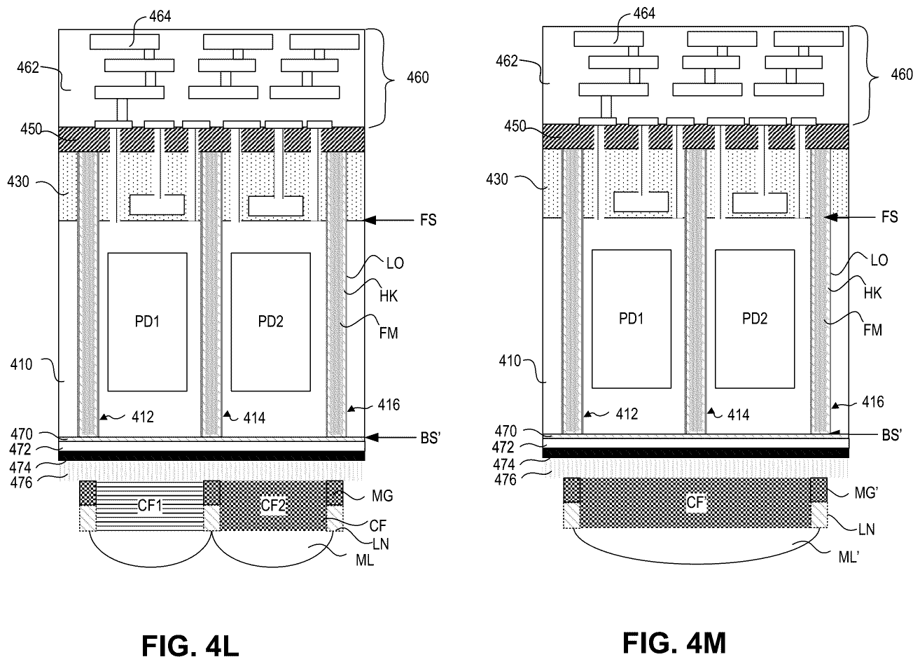

FIG. 4A-4M illustrate cross-sectional diagrams for fabrication states associated with the method 300 illustrated in FIG. 3A-3B, in accordance with an embodiment of the disclosure. In other words, FIG. 4A-4M illustrate fabrication states depicting an example manufacturing process for forming an example image sensor (e.g., image sensor 200) with a full deep trench isolation structure that provides full isolation between adjacent photodiodes, pixel, and/or pixel cells within a semiconductor substrate. More specifically, the fabrication states depicted by FIG. 4A-4M may be representative of one or more process blocks 301-335 included in the method 300 of FIG. 3A-3B. As such, it is understood that one or more of FIG. 4A-4M may represent a temporary structure as fabrication proceeds through the example method 300 including multiple fabrication, refining, and finishing steps, not all of which are necessarily illustrated. In some embodiments, the process blocks 301-335 of the method 300 can be repeated, reordered, or omitted. It is appreciated that some elements may be omitted to focus on the description on fabricating a deep trench isolation structure (e.g., deep trench isolation structure 227 of FIG. 2A-2B). It is appreciated that various processing operations have been implemented to form the illustrated structures shown in FIG. 4A-4M, but such operations may not all be explicitly disclosed (e.g., photoresist deposition, patterning, and/or removal). Rather, one of ordinary skill in the art having the benefit of the disclosure will be able to fabricate an image sensor based on the method 300 illustrated in FIG. 3A-3B and the cross-sectional diagrams illustrated in FIG. 4A-4M. Additionally, at least some of the intermediate states shown in FIG. 4A-4M may be optional or alternative forms, where applicable, in accordance with embodiments of the disclosure.

Process block 301 illustrates forming photodiode doped regions for photodiodes, floating diffusion regions, source/drain regions for pixel transistors, ground contacts (e.g., P+ doped regions) in or on a semiconductor substrate. In embodiments, photodiode doped regions of photodiodes, floating diffusion regions (not illustrated), sources/drains (not illustrated) may be formed monolithically on a common semiconductor substrate. FIG. 4A is representative of block 301 and shows semiconductor substrate 410 having photodiode doped regions corresponding to a plurality of photodiodes, floating diffusion regions (not illustrated), and source/drain regions (not illustrated) formed within semiconductor substrate 410. As illustrated, semiconductor substrate 410 includes a plurality of photodiodes (e.g., photodiodes PD1, PD2), floating diffusion regions (not illustrated), sources/drains (not illustrated) for one or more pixels or pixel cells. The semiconductor substrate 410 has a front side FS (e.g., non-illuminated side) and a backside BS (e.g., illuminated side) opposite the front side FS. Photodiode doped regions of the plurality of photodiodes, floating diffusion regions (not illustrated), source/drain regions, and contact regions may be disposed proximate to the front side and formed via one or more implantation steps at one or more implantation energies through the front side. In some embodiments, semiconductor substrate 410 may have a thickness T1 (see, e.g., FIG. 4B) on the order of hundreds of micrometers (e.g., 600 μm to approximately 700 μm).

It is appreciated semiconductor substrate 410 may correspond to a part of or an entirety of a semiconductor wafer (e.g., a silicon wafer). In some embodiments, the semiconductor substrate 410 includes or is otherwise formed of silicon, a silicon germanium alloy, germanium, a silicon carbide alloy, an indium gallium arsenide alloy, any other alloys formed of III-V group compounds, combinations thereof, one or more epitaxial layers of the aforementioned materials, or a bulk substrate thereof. More specifically, the semiconductor substrate 410 may correspond to any semiconductor material or combination of materials that may be doped or otherwise configured to facilitate formation of a photosensitive region of the respective pixel or pixel cell (e.g. photodiodes PD1 and PD2 illustrated in FIG. 4A, photodiodes 212, 214, 216, and 218 illustrated in FIG. 2A-2B, pixel cells PC1 and PC2 illustrated in FIG. 2A-2B, photodiodes included in plurality of pixels 1051 illustrated in FIG. 1B, and photodiodes included in pixel array 105 illustrated in FIG. 1A). For example, in some embodiments, the semiconductor substrate 410 may correspond to one or more epitaxial layers (e.g., P or N doped silicon) formed on a carrier or base substrate wafer. In such an embodiment, photodiodes (e.g., PD1, PD2), floating diffusion regions, source/drain regions or the like included in a respective pixel or pixel cell may be formed in the one or more epitaxial layers corresponding to the semiconductor substrate 410 while the carrier or support wafer may be removed or otherwise thinned during fabrication. For example, photodiodes (e.g., PD1, PD2), floating diffusion regions, source/drain regions or the like included in a respective pixel or pixel cell may be formed by ion implantation through the surface defined by the front side FS of the semiconductor substrate 410 with various implantation energies. In one embodiment, the semiconductor substrate 410 is formed of intrinsic or extrinsic silicon having regions doped sufficiently with an appropriate type of impurities to form a photodiode region for forming photodiodes (e.g., photodiode PD1, PD2) capable of photogenerating image charge in response to incident light.

Process block 303 shows forming gates for pixel transistors in or on the semiconductor substrate. Examples of gates include source-follower gate SF, row select gate RS, reset gate RST, and transfer gates 222, 224, 226, 288 respectively illustrated in FIG. 2A, which may be representative of gates 420 illustrated in FIG. 4B. Gates or gate electrodes for pixel transistors may be formed proximate to the front side FS of the semiconductor substrate 410.

Process block 305 illustrates performing an optional first annealing process for activating dopants in the semiconductor substrate. In some embodiments, the temperature for the first annealing process is at least greater than or equal to 800° C. and the duration for the first annealing process may range from 30 minutes to 2 hours, for example. In some embodiments, the temperature for the first annealing process is from 800° C. to 1200° C.

Process block 307 illustrates forming an inter-layer dielectric layer over the front side of the semiconductor substrate to encapsulate the gates of the pixel transistors. FIG. 4B is representative of block 307 and shows a dielectric material (e.g., oxide-based material) deposited in accordance with a CMOS-compatible deposition processes (e.g., chemical vapor deposition) to form an inter-layer dielectric layer 430 over a surface corresponding to the front side FS of the semiconductor substrate 410. In some embodiments, the inter-layer dielectric layer 430 may be formed of a tetraethylorthosilicate (TEOS) material and/or a high density plasma (HDP) oxide material. In some embodiments, the inter-layer dielectric layer 430 is planarized after deposition (e.g., via chemical mechanical polishing). As illustrated, the inter-layer dielectric layer 430 encapsulates or otherwise encloses a plurality of gates 420 (e.g., transfer gates, source follower gates, reset gates, row selects gate for the transistors associated with pixel cells). In some embodiments, inter-layer dielectric layer 430 corresponds to a closest dielectric layer formed on front side FS of semiconductor substrate 110 or on a pre-metal dielectric layer (not illustrated). In other words, in some embodiments, inter-layer dielectric layer may be directly coupled to front side FS of semiconductor substrate 410 or a pre-metal dielectric layer that also encapsulates or surrounds gate electrodes associated with pixel-level transistors. In some embodiments, the inter-layer dielectric layer 430 may have a thickness T2 (e.g., along a depthwise or vertical direction perpendicular to front side FS of semiconductor substrate 410) ranging from 200 nanometers to 400 nanometers.

Process block 309 shows etching through the inter-layer dielectric layer and into the semiconductor substrate to form a plurality of interconnected trenches defining photodiode or pixel areas within the semiconductor substrate. FIG. 4C-4E are representative of process block 309, which collectively show etching through inter-layer dielectric layer 430 and into semiconductor substrate 410 to form a plurality of trenches 412, 414, 416 (e.g., interconnected deep trenches) disposed proximate to respective photodiodes PD1, PD2 disposed within semiconductor substrate 410. As illustrated, inter-layer dielectric layer 430 is disposed over the front side FS of semiconductor substrate 410 such that the front side FS is disposed between inter-layer dielectric layer 430 and the backside BS of the semiconductor substrate 410.

In some embodiments, forming trenches 412, 414, and 416 is a multi-step process that includes forming a patterned photoresist layer 440 over inter-layer dielectric layer 430 as illustrated in FIG. 4C. Patterned photoresist layer 440 includes a plurality of openings 442, 444, 446 to facilitate selectively removing material from inter-layer dielectric layer 430. The plurality of openings 442, 444, 446 correspond to the location of the deep trench isolation structure (e.g., deep trench isolation structure 227 of FIG. 2A-2B) to be formed in the semiconductors substrate 410. More specifically, plurality of openings 442, 444, 446 are used to perform a first etching process to remove material of inter-layer dielectric layer 430 through plurality of openings 442, 444, 446 to respectively form plurality of trench openings 432, 434, 436 that extend entirely through inter-layer dielectric layer 430 until reaching semiconductor substrate 410 (e.g., front side FS) as illustrated in FIG. 4D. In some embodiments, each of plurality of trench openings 432, 434, 436 have a trench width W1 along a direction parallel to front side FS of semiconductor substrate 410 (e.g., a horizontal or lateral direction) as illustrated in FIG. 4E. In the same or other embodiments, each of plurality of trench openings 432, 434, 436 has a depth (e.g., perpendicular to the width W1 corresponding to a vertical direction perpendicular to a surface of the inter-layer dielectric layer 430 and/or front side FS of the semiconductor substrate 410) that is substantially the same or equal to the thickness T2 of the inter-layer dielectric layer 430.

In some embodiments, the patterned photoresist layer 440 is removed after performing the second etching process. For example, the patterned photoresist layer 440 and/or the plurality of trench openings 432, 434, 436 formed in the inter-layer dielectric layer 430 may be used as an etching mask to form trenches 412, 414, 416 (e.g., deep interconnected trenches) in the semiconductor substrate. In order words, a second etching process is performed to remove material of semiconductor substrate 410 by etching through the plurality of trench openings 432, 434, 436 to form trenches 412, 414, 416 that extend through inter-layer dielectric layer 430 and into semiconductor substrate 410 as illustrated in FIG. 4E. It is appreciated that trenches 412, 414, 416 in some embodiments are deep interconnected trenches that may serve the basis for forming deep trench isolation structure 227 illustrated in FIG. 2A-2B and deep trench isolation structure 127 illustrated in FIG. 1B. In order words, while the cross-sectional view shown in FIG. 4A-4M show distinct and separate trenches, when viewed from a plan view (e.g., as shown in FIG. 1A-2B), the trenches are interconnected to form a grid structure.

Referring back to FIG. 4E, trenches 412, 414, 416 may extend a trench depth D1 into the semiconductor substrate 410 with respect to front side FS surface. In one embodiment, trench depth D1 is from 2.5 micrometers to 8 micrometers depending on a final thickness of semiconductor substrate 410. In some embodiments, a width W2 of trenches 412, 414, 416 extending through the semiconductor substrate 410 is substantially the same as the width W1 the trenches 412, 414, 416 extend through inter-layer dielectric layer 430. It is appreciated in some embodiments, width W1 and width W2 are along a direction parallel to front side FS of the semiconductor substrate 410. In the same or other embodiments, each of 412, 414, 416 may have a substantially constant trench width throughout (e.g., width W1 and/or with W2 is constant through an entire depth T2 and/or D1, respectively). In some embodiments, width W1 and/or width W2 is from 90 nanometers to 170 nanometers (e.g., from 90 nanometers to 120 nanometers, from 110 nanometers to 170 nanometers, or interpolations thereof). In some embodiments, trench depth D1 may be configured based on a target final substrate thickness (e.g., thickness T1′ of FIG. 4J) of semiconductor substrate 410.

Process block 311 illustrates applying a second annealing process to the inter-layer dielectric layer to improve reliability of the image sensor. In some embodiments, the second annealing process is from 700° C. to 850° C. for at least 30 minutes. The second annealing process may occur after forming the plurality of interconnected trenches (e.g., deep trenches such as trenches 412, 414, 416 illustrated in FIG. 4E) such that the semiconductor substrate that may have been damaged by the second etching processes may receive the benefit of the second annealing process. For example, in one embodiment, the second annealing process is a high temperature annealing process (e.g., hydrogen annealing) capable of mitigating or curing damage or defects to improve reliability of the image sensor. In one embodiment, the second annealing process is applied from the front side of the semiconductor substrate at high temperature (700° C. to 850° C. for at least 30 minutes) while exposing the semiconductor substrate (e.g., through trenches 412, 414, 416 illustrated in FIG. 4E) to atoms such as hydrogen and/or fluorine to cure dangling bonds generated by etching damage (e.g., induced by the second etching process), which can mitigate defects and thus improve white pixel and dark current performance associated with the image sensor.

It is appreciated that in some embodiments, the first annealing process of block 305 may be referred to as a highest temperature annealing process of the method 300 and the second annealing process of block 311 may be referred to as a second highest annealing process. In other words, a temperature of the first annealing process is greater than a temperature of the second annealing process. However, in other embodiments, the first annealing process of block 305 may be omitted and annealing process of block 3011 may be a highest temperature annealing process of the method 300 and provide both dopant activation and defect curing. In other words, the first annealing process of block 305 and the second annealing process of block 311 may be combined into a single annealing process with appropriate temperature (e.g., from 750° C. to 1100° C.). In some embodiments, the combined annealing process may have the highest temperature of all the manufacturing processes for fabricating the example image sensor.

Process block 313 shows applying a first thermal oxidation to form a liner layer passivating sidewalls bottom surfaces of the plurality of interconnected trenches defining photodiode or pixel areas within the semiconductor substrate. FIG. 4F is representative of process block 313, in part, and shows performing a first thermal oxidation process to form liner oxide layer LO conformally coating sidewalls and a bottom surface of trenches 412, 414, 416 (e.g., before depositing fill material FM). It is appreciated liner oxide layer LO may passivate sidewalls and bottom surfaces of trenches 412, 414, 416 and further protect the underlying surfaces of semiconductor substrate 410 during subsequent processing steps. In some embodiments, a thickness T_{LO} of liner oxide layer LO is from 1.0 nanometers to 3.0 nanometers. In some embodiments, the liner oxide layer LO is formed by a plasma oxidation process using a decoupled plasma oxidation reactor.

Process block 315 illustrates forming a first high-κ material layer (e.g., aluminum oxide, hafnium oxide, tantalum oxide, or other high-κ material having a relative dielectric constant greater than 3.9 or silicon dioxide). FIG. 4F is also representative of process block 315, in part, and shows depositing a first high-κ material HK within trenches 412, 414, 416. In the illustrated embodiment, first high-κ material HK conformally coats liner oxide layer LO to form a layer of high-κ material lining liner oxide layer LO. In some embodiments, first high-κ material HK may be conformal to a profile of trenches 412, 414, 416. In some embodiments, a thickness of first high-κ material HK lining or coating liner oxide layer LO is from 2.0 nanometers to 80.0 nanometers. In the same or other embodiments, first high-κ material HK may partially fill trenches 412, 414, 416. In some embodiments, first high-κ material HK is deposited using an atomic layer deposition process. In the same or other embodiments, first high-κ material HK includes aluminum oxide, hafnium oxide, tantalum oxide, or combinations thereof.

Process block 317 shows depositing a fill material within the plurality of interconnected trenches defining photodiode or pixel areas to form a deep trench isolation structure configured to isolate individual photodiodes from adjacent photodiodes (or pixels from adjacent pixels) included in the image sensor. FIG. 4F is also representative of process block 317, in part, and shows depositing fill material FM into trenches 412, 414, 416 to form a deep trench isolation structure that isolates photodiodes (e.g., PD1, PD2) from one another. In some embodiments, fill material FM may be a dielectric or insulating material (e.g., an oxide-based material such as silicon dioxide) or a conductive material (e.g., polysilicon or metal). In some embodiments, fill material FM may have a refractive index lower than a refractive index of a substrate region of the semiconductor substrate 410

Process block 319 shows applying a chemical mechanical polishing process to remove excess material (e.g., coating the inter-layer dielectric layer). It is appreciated that in some embodiments, process blocks 313, 315, and 317 may result in one or more of the liner layer, the first high-κ material, and/or the fill material to be formed or deposited on an exposed surface of the inter-layer dielectric layer. For example, referring to FIG. 4F, liner oxide LO, first high-κ material HK, and/or fill material FM may each form respective layers on the surface of inter-layer dielectric layer 430. It is appreciated that in some embodiments, the material deposited from process blocks 313, 315, and 317 outside of or otherwise beyond the confines of the trenches 412, 414, 416 may be considered excess material. Accordingly, a chemical mechanical polishing process may be utilized to remove one or more of liner oxide LO, first high-κ material HK, and/or fill material FM from a surface of inter-layer dielectric layer 430 while also forming a planar surface of inter-layer dielectric layer 430 for subsequent processing steps.

Referring back to FIG. 4F, each of trenches 412, 414, 416 that extend through inter-layer dielectric layer 430 and into semiconductor substrate 410 is collectively filled by liner oxide LO, high-κ material HK, and fill material FM to form a deep trench isolation structure. As previously discussed, the deep trench isolation structure formed from trenches 412, 414, 416 is an interconnected grid structure (see, e.g., FIG. 1B-2B) that surrounds and separates individual photodiodes, pixel regions, and/or pixel cells within semiconductor substrate 410 and inter-layer dielectric layer 430. In illustrated embodiment of FIG. 4F, a first part (or upper trench portion UT) of each of trenches 412, 414, 416 formed within the inter-layer dielectric layer 430. The first part (or upper trench portion UT) of each of trenches 412, 414, 416 includes the first high-κ material HK disposed between the fill material FM and the liner oxide material LO since the first high-κ material HK is deposited after performing the first thermal oxidation process and before the depositing the fill material. In the same or other embodiments, the liner oxide material LO and the first high-κ material HK are disposed between the inter-layer dielectric layer 430 and the fill material FM. A same arrangement for liner oxide material LO, first high-κ material HK, and fill material FM is also shown in a second part (or lower trench portion LT) of each of trenches 412, 414, 416 that is formed within semiconductor substrate 410. In other words, within the lower trench portion LT, the first high-κ material HK is disposed between the fill material FM and the liner oxide material LO. Put in another way, for both the first portion and the second portion of trenches 412, 414, 416, fill material FM is surrounded or enclosed by first high-κ material HK and first high-κ material HK is in turn surrounded or enclosed by liner oxide material LO.

Process block 321 illustrates forming a capping layer on the inter-layer dielectric layer. FIG. 4G is representative of process block 321 and shows depositing an oxide-based material to cover a top surface of the inter-layer dielectric layer 430 to form capping layer 450. As illustrated, the inter-layer dielectric layer 430 is disposed between front side FS of the semiconductor substrate 410 and the capping layer 450. More specifically, capping layer 450 is formed on the top surface of the inter-layer dielectric layer 430 that has a deep trench isolation structure embedded therein (e.g., formed by trenches 412, 414, 416). In some embodiments, capping layer 450 may protect trenches 412, 414, 416 and material disposed therein (e.g., liner oxide material LO, first high-κ material HK, and fill material FM) from subsequent processing steps (e.g., such that exposed portions of the deep trench isolation structure is not damaged by subsequent processing steps).

Process block 323 shows forming a plurality of contacts on the inter-layer dielectric layer, or more specifically, on the capping layer. FIG. 4H is representative of process block 323 and shows forming plurality of contacts 455 extending through capping layer 450 and inter-layer dielectric layer 430 to electrically connect or couple corresponding pixel elements (e.g., gates or gate electrodes, floating diffusion regions, source/drain regions of pixel transistors) for signal routing. In some embodiments, one or more of plurality of contacts 455 lands on a surface of front side FS of semiconductor substrate 410.

Process block 325 illustrates forming a metallization layer (e.g., one or more layers or metal wires and/or vias embedded within one or more inter-metal dielectric layers) for signal routing. The one or more metal wires and/or vias may collectively be referred to as a plurality of metal interconnects that are embedded within one or more inter-metal dielectric layers. In some embodiments, the plurality of metal interconnects is coupled to the plurality of contacts to provide signal routing. FIG. 4I is representative of process block 325 and shows metallization layer 460 including four metal layers, each including a plurality of metal interconnects 464 embedded in an inter-metal dielectric layer 462. In some embodiments, metallization layer 460 may include one or more metal layers having one or more metal interconnects (e.g., metal wires or vias) formed of a conductive material such as Au, Al, Cu, W, one or more alloys such as an aluminum alloy, other conductive materials, or combinations thereof to provide signal routing.

Process block 327 shows thinning the semiconductor substrate from a backside (i.e., opposite the front side of the semiconductor substrate previously used to form the trenches) of the semiconductor substrate to expose portions or surfaces of the deep trench isolation structure proximate to the backside of the semiconductor substrate. FIG. 4J is representative of process block 327 and shows backside processing of the example image sensor by thinning the backside BS of the semiconductor substrate 410 to expose the backside of trenches 412, 414, 416 (i.e., surface 412B, 414B, 416 of deep trench isolation structures). As illustrated in FIG. 4J, a portion of the semiconductor substrate 410 proximate to the backside BS is removed from the backside BS such that the deep trench isolation structure extends entirely through the thinned semiconductor substrate 410 (e.g., remaining or final bulk substrate, wafer substrate, or epitaxial layer). In some embodiments, portions of the deep trench isolation structures proximate to the backside BS is also removed during the thinning process of the semiconductor substrate 410. In one embodiment, etching and/or chemical mechanical polishing is utilized to thin semiconductor substrate 410 to form a backside BS′ (e.g., the backside of semiconductor substrate 410 opposite front side FS after thinning) that exposes a distal end of the lower trench portion LT of trenches 412, 414, 416 of the deep trench isolation structure. Accordingly, the deep trench isolation structure formed by trenches 412, 414, 416 has a depth that is substantially the same thickness T1′ of the semiconductor substrate 410. In other words, the deep trench isolation structure has become a full trench isolation structure or through substrate structure after completion of thinning process and may be referred to as a full front-side deep trench isolation structure that provides full isolation between adjacent photodiodes (e.g., photodiodes PD1, PD2), adjacent pixels, and/or pixel cells within the semiconductor substrate. In some embodiments, thickness T1′ of the semiconductor substrate 410 is the final thickness of the semiconductor substrate 410. In some embodiments, thickness T1′ of the semiconductor substrate 410 may range from 2.5 micrometers to 7 micrometers.

Process block 329 illustrates applying a second thermal oxidation process to a backside of the semiconductor substrate to form a thin oxide layer passivating the backside (e.g., thinned) surface of the semiconductor substrate. FIG. 4K is representative of process block 329, in part, and shows performing a second thermal oxidation process to form a thin oxide layer 470 over the backside BS′ on the backside BS′ of the semiconductor substrate 410 to provide a surface passivation effect to the backside BS′. In some embodiments, thin oxide layer 470 is from 1.5 to 2.0 nanometers thick. It is appreciated that in some embodiments, process block 329 may be omitted.

Process block 331 shows forming a second high-κ material layer over the backside surface to enclose the exposed portions of the deep trench isolation structure proximate to the backside. FIG. 4K is also representative of process block 331, in part, and shows depositing a second high-κ material 472 on the thin oxide layer 470 such that the thin oxide layer 470 is disposed between the backside BS′ of the semiconductor substrate 410 and the second high-κ material 472. As illustrated, proximate to the backside BS′ of semiconductor substrate 410, the first high-κ material HK may be disposed between the fill material FM and the second high-κ material 472 in a direction perpendicular to the backside surface. In some embodiments, the layer formed by the second high-κ material 472 has a thickness from 5.0 nanometers to 8.0 nanometers. In the same or other embodiments, the second high-κ material 472 is formed by an atomic layer deposition process. As illustrated, the second high-κ material 472 is deposited to cover the backside BS′ of the semiconductor substrate 410 and may be formed on the thin oxide layer 470. In some embodiments, a thickness of the layer formed by the second high-κ material 472, T_{SECOND HK}, is the same as a thickness of the layer formed by the first high-κ material HK, T_{FIRST HK}. In some embodiments, the second high-κ material includes aluminum oxide, hafnium oxide, tantalum oxide, or combinations thereof.

Process block 333 illustrates forming an anti-reflective layer on the layer formed by the second high-κ material while process block 335 shows forming subsequent backside elements (e.g., metal grid, color filter, microlens, pad formation, and the like). FIG. 4L and FIG. 4M are representative of process blocks 333 and 335 and shows anti-reflective layer 474 formed on the second high-κ material 472. FIGS. 4L and 4M further shows a planarization layer 476 (e.g., an oxide-based buffer layer) formed on the anti-reflective layer 474 and a metal grid structure (e.g., MG for FIG. 4L and MG′ for FIG. 4M) formed on the planarization layer 476. FIGS. 4L and 4M further show a color filter array including a plurality of color filters (e.g., CF1, CF2 for FIG. 4L and CF′ for FIG. 4M) formed on planarization layer 476. It is appreciated that the plurality of color filters is aligned with a respective underlying photodiode (e.g., for FIG. 4L, color filter CF1 is optically aligned with PD1 and color filter CF2 is optically aligned with PD2 while for FIG. 4M color filter CF′ is optically aligned with both PD1 and PD2). FIGS. 4L and 4M further show a microlens array (e.g., microlenses ML for FIG. 4L and microlenses ML′ for FIG. 4M) formed on the color filter array (e.g., CF1, CF2, CF′). In some embodiments, additional dielectric layer LN may be disposed on the corresponding metal grid structure to form a composite metal grid structure, wherein the dielectric layer LN may be formed of or otherwise include an oxide material or a dielectric material having a refractive index lower than adjacent color filters included in the plurality of color filters. While not described in detail, it is understood that processes for forming the color filter array can include patterned polymer deposition (e.g., via photolithography) followed by planarization (e.g., via chemical mechanical polishing configured for planarizing a polymer surface). Similarly, the microlens array can be fabricated separately and subsequently transferred onto the color filter array.

It is appreciated that each microlens included in the microlens array (e.g., ML or ML′) illustrated in FIGS. 4L and 4M is disposed over or on a corresponding color filter included in the color filter array (e.g., CF1, CF2, CF′) and is optically aligned with a corresponding photodiode (e.g., PD1, PD2) for directing incident light to the corresponding photodiode. In some embodiments, FIG. 4L may be representative of a cross-sectional along the line X-X′ of FIG. 2A. In the illustrated embodiment of FIG. 4L, photodiodes PD1, PD2 may be in different pixel cells and thus receive different wavelength ranges of light. For example, CF1 may correspond to a red color filter while CF2 may correspond to a green color filter to respectively form a red pixel and a green pixel. As illustrated in FIG. 4L, separate microlens are employed to direct incident light to individual photodiodes (e.g., photodiode PD, PD2 are in different pixel cells). In contrast, FIG. 4M shows a same color filter CF′ and a same microlens ML′ optically aligned with photodiodes PD1, PD2 (e.g., PD1 and PD2 are in a same pixel cell). It is appreciated the metal grid structure (e.g., MG for FIG. 4L and MG′ for FIG. 4M) may isolate pixel cells (e.g., provides optical isolation between color filters having different spectral photoresponses).

Referring back to FIG. 4L or FIG. 4M, the image sensor includes a photodiode (e.g., PD1, PD2) disposed within semiconductor substrate 410 having a front side FS and a backside BS′ opposite of the front side FS. The image sensor further includes an inter-layer dielectric layer 430 disposed over the front side FS of the semiconductor substrate 410 such that the front side FS is disposed between the inter-layer dielectric layer 430 and the backside BS. The image sensor further includes a deep trench isolation structure configured to isolate the photodiode (e.g., PD1, PD2) from adjacent photodiodes (e.g., PD2, PD1) included in the image sensor. As illustrated, the deep trench isolation structure includes a trench (e.g., trench 412, 414, 416) disposed within inter-layer dielectric layer 430 and semiconductor substrate 410. In the illustrated embodiment, the trench (e.g., 412, 414, 416) extends through the inter-layer dielectric layer 430 and the front side FS of the semiconductor substrate 410 toward the backside BS′ of the semiconductor substrate 410. As illustrated, a fill material FM is disposed within the trench.

In some embodiments, a first width (e.g., W1 illustrated in FIG. 4E) of a first portion (e.g., upper trench portion UT illustrated in FIG. 4F) of the trench (e.g., 412, 414, 416) is substantially equal (e.g., within 5%) to a second width (e.g., W2 illustrated in FIG. 4E) of a second portion (e.g., lower trench portion LT illustrated in FIG. 4F) of the trench disposed within the semiconductor substrate 410. In some embodiments, the first width and the second width each extend along a direction parallel to the front side FS of the semiconductor substrate 410. In the same or other embodiments, the second portion extends a full depth (e.g., T1′ illustrated in FIG. 4J) of the semiconductor substrate 410. In some embodiments, the trench (e.g., 412, 414, 416) of the deep trench isolation structure has a substantially uniform trench width along a direction parallel to the front side FS of the semiconductor substrate 410.

As illustrated in FIGS. 4M and 4L, the deep trench isolation structure further includes a liner oxide material LO and a first high-κ material HK disposed within the trench. As illustrated, the first high-κ material HK is disposed between the fill material FM and the liner oxide material LO for a first portion (e.g., upper trench portion UT illustrated in FIG. 4F) of the trench (e.g., 412, 414, 416) disposed within the inter-layer dielectric layer 430. In the same or other embodiments, the liner oxide material LO conformally coats sidewalls and a bottom surface of the trench (e.g., 412, 414, 416) to form a nested trench disposed within the trench. In some embodiments, the first high-κ material conformally coats sidewalls and a bottom surface of the nested trench such that the first high-κ material HK is encircled, encapsulated, or otherwise laterally surrounded by the liner oxide material LO.

In some embodiments, a thickness (e.g., T_{LO} illustrated in FIG. 4F) of the liner oxide material LO disposed within the trench (e.g., 412, 414, 416) is less than a thickness (e.g., T_{FIRST HK} illustrated in FIG. 4F) of the first high-κ material HK disposed within the trench. In the same or other embodiments, the deep trench isolation structure illustrated in FIG. 4L-4M includes a thin oxide layer 470 and a second high-κ material 472 disposed on the thin oxide layer 470 such that the thin oxide layer 470 is disposed between the backside BS of the semiconductor substrate 410 and the second high-κ material 472. In the same or other embodiments, the first high-κ material HK is disposed between the fill material FM and the second high-κ material 472.

In the same or other embodiments, the image sensor further includes a gate electrode (e.g., gate 420 illustrated in FIG. 4B) disposed within the inter-layer dielectric layer 430 and the first high-κ material HK disposed within the trench (e.g., trenches 412, 414, 416 illustrated in FIG. 4L-4M). In some embodiments, the first high-κ material HK is disposed between the gate electrode 420 and the fill material FM. In the illustrated embodiment of FIG. 4L-4M, the image sensor further includes a capping layer 450 covering a top surface of the inter-layer dielectric layer 430 such that the inter-layer dielectric layer 430 is disposed between the front side FS of the semiconductor substrate 410 and the capping layer 450. In some embodiments, the first high-κ material HK, the liner oxide layer LO, and/or the fill material FM disposed within the inter-layer dielectric layer 430 is disposed between the capping layer 450 and second high-κ material 472 formed on or proximate to the backside BS′ of the semiconductor substrate 410.

In some embodiments, the image sensor includes a contact structure (e.g., plurality of contacts 455) extending through the capping layer 450 and the inter-layer dielectric layer 430 until reaching the front side FS of the semiconductor substrate 410. In the same or other embodiments, the contact structure extends adjacent to the deep trench isolation structure (e.g., trench 412, 414, 416) disposed within the inter-layer dielectric layer 430. As illustrated in FIG. 4L-4M, the image sensor further includes a metallization layer 460 including a plurality of metal interconnects 464. In some embodiments, the inter-layer dielectric layer 430 is disposed between the semiconductor substrate 410 and the metallization layer 460. In some embodiments, the fill material FM includes a metal material or a polysilicon material. In the same or other embodiments, the fill material FM of the deep trench isolation structure is configured to receive a biasing voltage routing by the plurality of metal interconnects 464. As illustrated in FIG. 4L-4M, when viewed in context of embodiments of the disclosure (e.g., in context of FIG. 1B-2B), the deep trench isolation structure extends laterally around photodiodes (e.g., PD1, PD2) to isolate the photodiode from adjacent photodiodes included in the image sensor.

In some embodiments, the deep trench isolation structure further includes a dielectric capping material disposed within the trench to form a dielectric cap structure extending into the semiconductor substrate from the backside of the semiconductor substrate. More specifically, method 300 may include one or more additional steps prior to block 313 (e.g., prior to applying a first thermal oxidation) and/or prior to block 315 (e.g., prior to forming the first high-κ material layer) to form the dielectric cap structure.

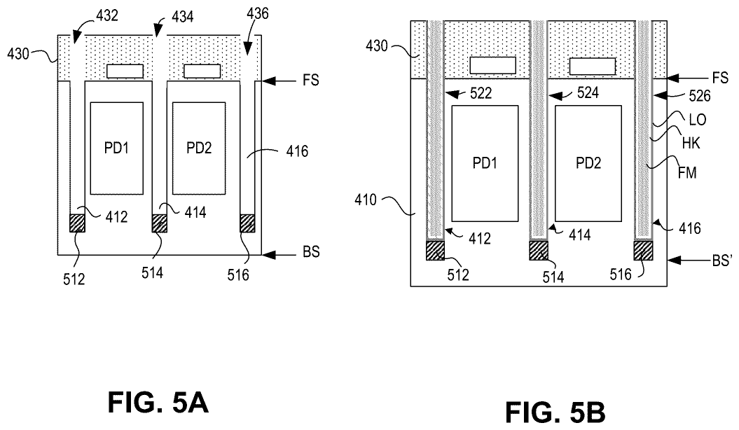

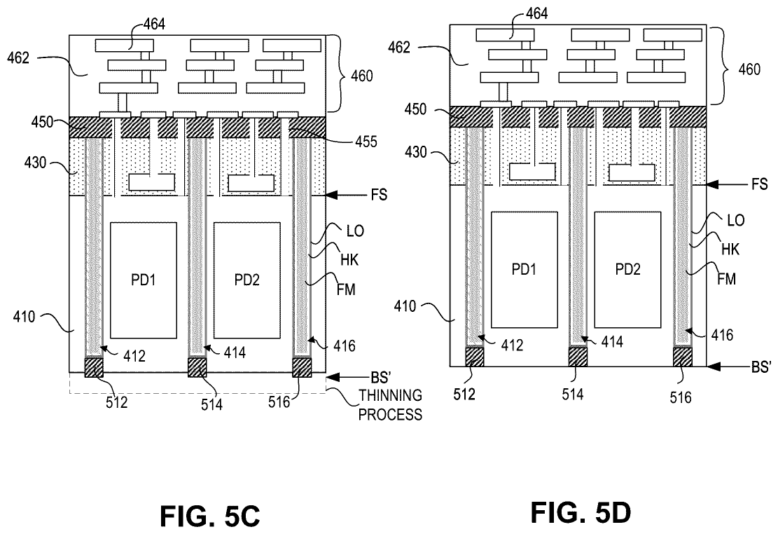

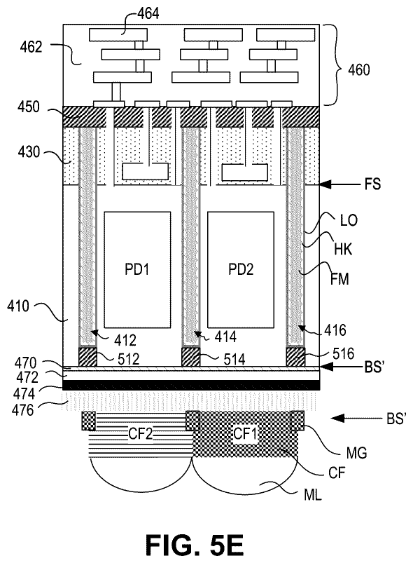

FIG. 5A-5E represent fabrication states for forming an image sensor including a deep trench isolation structure with a dielectric cap structure to protect the deep trench isolation structure from being damaged during backside thinning or etching (e.g., process block 327), in accordance with an embodiment of the disclosure.

As illustrated in FIG. 5A, a dielectric capping material is deposited within the trenches 412, 414, 416 through trench openings 432, 434, 436 to form dielectric cap structure 512, 514, 516 extending from a bottom of the trenches 412, 414, 416 proximate to the backside BS of the semiconductor substrate 410 before depositing the first high-κ material (e.g., process block 315) and before depositing the fill material (e.g., 317). It is appreciated that the dielectric capping material may be deposited before or after the first thermal oxidation process (e.g., process block 313). Accordingly, the first high-κ material HK is disposed between the dielectric capping material (e.g., material deposited for dielectric cap structure 512, 514, 516) and the fill material FM (see, e.g., FIG. 5B-5E). In some embodiments, dielectric cap structures 512, 514, 516 may also serve as an etch stop during the backside thinning or etching process to prevent damage to high-κ material HK.

After formation of dielectric cap structures 512, 514, 516 in each of the trenches 412, 414, 416, the liner oxide layer LO, the first high-κ material HK, and the fill material FM may be sequentially deposited into the trenches 412, 414, 416 to form the deep trench isolation structure (i.e., trenches 412, 414, 416 filled with dielectric cap structures 512, 514, 516, liner oxide layer LO, the first high-κ material HK, and the fill material FM) as illustrated in FIG. 5B. In some embodiments, the liner oxide layer LO is disposed on dielectric cap structures 512, 514, 516 (e.g., liner oxide layer LO is disposed between dielectric cap structures 512, 514, 516 and fill material FM). In the same or other embodiments, the first high-κ material HK is disposed on the liner oxide layer LO and the fill material FM is disposed on the first high-κ material HK (e.g., the first high-κ material HK is disposed between the liner oxide layer LO and the fill material FM). In the same or other embodiments, the first high-κ material HK is disposed between the fill material FM and the dielectric cap structures 512, 514, 516. It is appreciated that the deep trench isolation structure illustrated by FIG. 4A-4D is an example of deep trench isolation structure 127 illustrated in FIG. 1B and deep trench isolation structure 227 illustrated in FIG. 2A-2B that formed an interconnected grid structure to isolate individual photodiodes, pixels, and/or pixel cells.

Fabrication of the image sensor continues in accordance with method 300 (e.g., FIG. 5B is representative of process blocks 313-319) and continues with process block 321-327 as illustrated in FIG. 5C in which capping layer 450, plurality of contacts 455, and metallization layer 460 are formed from the front side FS of the semiconductor substrate 410 followed by thinning the semiconductor substrate 410 from the backside BS to expose dielectric cap structures 512, 514, 516. In some embodiments, dielectric cap structures 512, 514, 516 may serve as an etch stop (e.g., dielectric cap structures provide etch selectivity relative to semiconductor substrate 410) and prevent damage to first high-κ material HK formed in trenches 412, 414, 416 proximate to backside BS′ of semiconductor substrate 410. In some embodiments, an etch-back process may be applied to remove excess material (e.g., a portion of the dielectric cap structure 512, 514, 516) to planarize and smooth surface of the backside BS′ of the semiconductor substrate 410 to facilitate subsequent processing (e.g., formatting of backside elements) as illustrated in FIG. 5D.

After thinning and planarization of the backside BS′ of the semiconductor substrate 410 illustrated in FIG. 5C-5D, fabrication of the image sensor continues with FIG. 5E showing backside elements (e.g., thin oxide layer 470, second high-κ material 472, anti-reflective layer 474, planarization layer 476, stack of metal grid structure MG and low n grid structure (not illustrated), barrier layer (not illustrated), color filter array CF including color filters CF1, CF2, microlens array ML, and the like) are formed corresponding to process blocks 329-335. As illustrated in FIG. 5E, a dielectric capping material is disposed within the trenches 412, 414, 416 to form dielectric cap structures 512, 514, 516 extending into the semiconductor substrate 410 from the backside BS′ of the semiconductor substrate 410. In the same or other embodiments, the fill material FM is disposed between the dielectric capping material of the dielectric capping structure 512, 514, 516 and the capping layer 450. In some embodiments, the dielectric capping material included in the dielectric cap structures 512, 514, 516 is disposed between the first high-κ material HK and the second high-κ material 472.

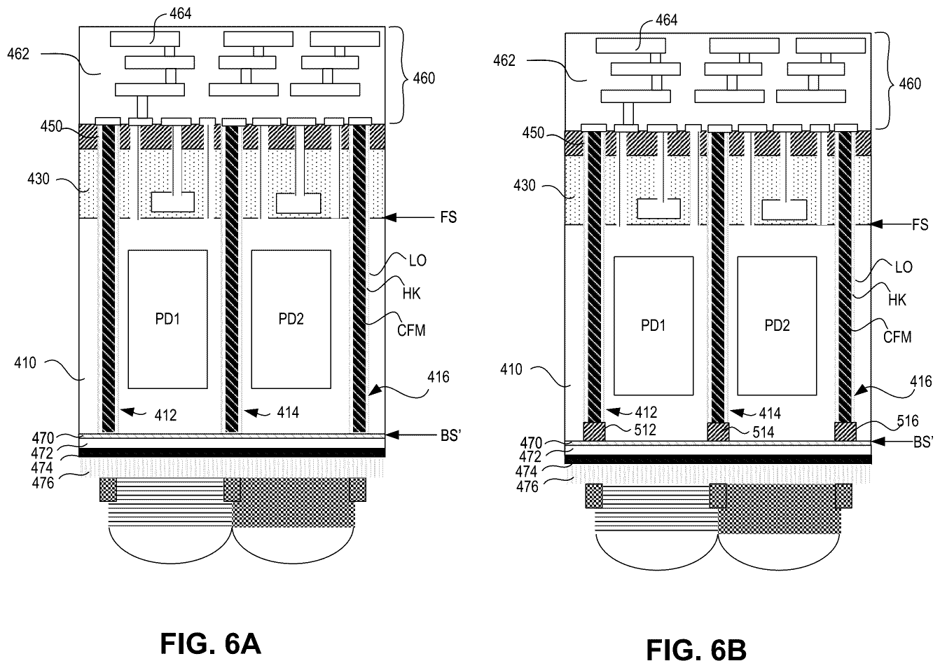

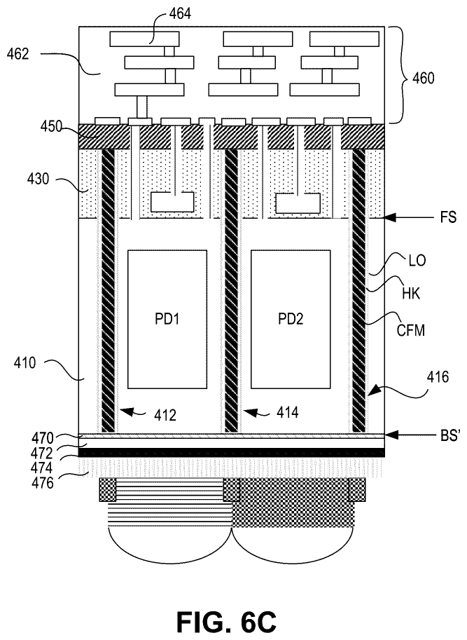

FIG. 6A-6C illustrate an embodiment in which the fill material FM of the deep trench isolation structure is coupled to receive a biasing voltage to provide enhanced passivation, in accordance with an embodiment of the disclosure. More specifically, the fill material FM includes a metal material or a polysilicon material that is configured to receive a biasing voltage routed by the plurality of metal interconnects 464. In such an embodiment, the fill material FM may be in contact with a metal layer (e.g., first metal layer) of the metallization layer 460 to receive the biasing voltage routed by metal interconnects 464. It is appreciated that the biasing voltage may be provided by control circuitry (e.g., control circuitry 121 of FIG. 1A).

In the illustrated embodiments of FIG. 6A-6B, the deep trench isolation structure further extends through capping layer 450 while in FIG. 6C the deep trench isolation structure does not extend through the capping layer 450 such that the capping layer 450 is disposed between trenches 412, 414, 416 of the deep trench isolation structure and the metallization layer 460 to separate and isolate the deep trench isolation structure from the plurality of metal interconnects 464 of the metallization layer 460.

It is appreciated that embodiments of the disclosure illustrated in FIG. 1A-6C may be fabricated using conventional semiconductor device processing and microfabrication techniques known by one of ordinary skill in the art, which may include, but is not limited to, photolithography, ion implantation, chemical vapor deposition, physical vapor deposition, thermal evaporation, sputter deposition, reactive-ion etching, plasma etching, wafer bonding, chemical mechanical planarization, and the like. It is appreciated that the described techniques are merely demonstrative and not exhaustive and that other techniques may be utilized to fabricate one or more components of various embodiments of the disclosure.

The above description of illustrated examples of the invention, including what is described in the Abstract, is not intended to be exhaustive or to limit the invention to the precise forms disclosed. While specific examples of the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific examples disclosed in the specification. Rather, the scope of the invention is to be determined entirely by the following claims, which are to be construed in accordance with established doctrines of claim interpretation.

What is claimed is:

1. An image sensor, comprising:
a photodiode disposed within a semiconductor substrate having a front side and a backside opposite the front side;
an inter-layer dielectric layer disposed over the front side of the semiconductor substrate such that the front side is disposed between the inter-layer dielectric layer and the backside; and
a deep trench isolation (DTI) structure configured to isolate the photodiode from adjacent photodiodes included in the image sensor, wherein the DTI structure includes:
a trench disposed within the inter-layer dielectric layer and the semiconductor substrate, wherein the trench extends through the inter-layer dielectric layer and the front side of the semiconductor substrate towards the backside of the semiconductor substrate; and
a fill material disposed within the trench.

2. The image sensor of claim 1, wherein a first width of a first portion of the trench disposed within the inter-layer dielectric layer is substantially equal to a second width of a second portion of the trench disposed within the semiconductor substrate, wherein the first width and the second width each extend along a direction parallel to the front side of the semiconductor substrate.

3. The image sensor of claim 2, wherein the second portion of the DTI structure extends through a full depth of the semiconductor substrate.

4. The image sensor of claim 1, wherein the trench of the DTI structure has a substantially uniform trench width along a direction parallel to the front side of the semiconductor substrate.

5. The image sensor of claim 1, wherein the DTI structure further comprises a liner oxide material and a first high-κ material disposed within the trench, wherein the first high-κ material is disposed between the fill material and the liner oxide material for a first portion of the trench disposed within the inter-layer dielectric layer.

6. The image sensor of claim 5, wherein the liner oxide material conformally coats sidewalls and a bottom surface of the trench to form a nested trench disposed within the trench, and wherein the first high-κ material conformally coats sidewalls and a bottom surface of the nested trench such that the first high-κ material is encircled by the liner oxide material.

7. The image sensor of claim 5, wherein a thickness of the liner oxide material disposed within the trench is less than a thickness of the first high-κ material disposed within the trench.

8. The image sensor of claim 5, further comprising:
a thin oxide layer formed on the backside of the semiconductor substrate; and
a second high-κ material disposed on the thin oxide layer such that the thin oxide layer is disposed between the backside of the semiconductor substrate and the second high-κ material, and wherein the first high-κ material is disposed between the fill material and the second high-κ material.

9. The image sensor of claim 8, further comprising a dielectric capping material disposed within the trench to form a dielectric cap structure extending into the semiconductor substrate from the backside of the semiconductor substrate, wherein the dielectric capping material is disposed between the first high-κ material and the second high-κ material.

10. The image sensor of claim 1, further comprising:
a capping layer covering a top surface of the inter-layer dielectric layer such that the inter-layer dielectric layer is disposed between the front side of the semiconductor substrate and the capping layer; and
a dielectric capping material disposed within the trench to form a dielectric cap structure extending into the semiconductor substrate from the backside of the semiconductor substrate, wherein the fill material is disposed between the dielectric capping material and the capping layer.

11. The image sensor of claim 10, further comprising a contact structure extending through the capping layer and the inter-layer dielectric layer until reaching the front side of the semiconductor substrate, wherein the contact structure extends adjacent to the DTI structure disposed within the inter-layer dielectric layer.

12. The image sensor of claim 1, further comprising a gate electrode disposed within the inter-layer dielectric layer and a first high-κ material disposed within the trench, and wherein the first high-κ material is disposed between the gate electrode and the fill material.

13. The image sensor of claim 1, further comprising a metallization layer including a plurality of metal interconnects, wherein the inter-layer dielectric layer is disposed between the semiconductor substrate and the metallization layer, wherein the fill material includes a metal material or a polysilicon material, and wherein the fill material of the DTI structure is configured to receive a biasing voltage routed by the plurality of metal interconnects.

14. The image sensor of claim 1, wherein the DTI structure extends laterally around the photodiode to isolate the photodiode from the adjacent photodiodes included in the image sensor.

15. A method of fabricating an image sensor, comprising:
etching through an inter-layer dielectric layer and into a semiconductor substrate to form a trench disposed proximate to a photodiode disposed within the semiconductor substrate, wherein the semiconductor substrate includes a front side and a backside opposite the front side, and wherein the inter-layer dielectric layer is disposed over the front side of the semiconductor substrate such that the front side is disposed between the inter-layer dielectric layer and the backside; and
depositing a fill material within the trench to form a deep trench isolation structure configured to isolate the photodiode from adjacent photodiodes included in the image sensor.

16. The method of claim 15, wherein the etching through the inter-layer dielectric layer and into the semiconductor substrate to form the trench includes:
forming a patterned photoresist layer over the inter-layer dielectric layer, wherein the patterned photoresist layer includes an opening;
performing a first etching process to remove material of the inter-layer dielectric layer by etching the inter-layer dielectric layer through the opening to form a trench opening;
removing the patterned photoresist layer;
performing a second etching process to remove material of the semiconductor substrate by etching through the trench opening to form the trench extending through the inter-layer dielectric layer and into the semiconductor substrate.

17. The method of claim 15, further comprising:
performing a first thermal oxidation process to form a liner oxide layer conformally coating sidewalls and a bottom surface of the trench before the depositing the fill material; and
depositing a first high-κ material within the trench, wherein the first high-κ material is disposed between the fill material and the liner oxide material for a first portion of the trench disposed within the inter-layer dielectric layer after the performing the first thermal oxidation process and before the depositing the fill material.

18. The method of claim 17, further comprising:
removing at least a portion of the semiconductor substrate from the backside to exposure the deep trench isolation structure from the backside such that the deep trench isolation structure extends entirely through the semiconductor substrate.

19. The method of claim 18, further comprising:
performing a second thermal oxidation process to form a thin oxide layer on the backside of the semiconductor substrate; and
depositing a second high-κ material on the thin oxide layer such that the thin oxide layer is disposed between the backside of the semiconductor substrate and the second high-κ material, and wherein the first high-κ material is disposed between the fill material and the second high-κ material.

20. The method of claim 18, further comprising:
depositing a dielectric capping material within the trench to form a dielectric cap structure extending from a bottom of the trench proximate to the backside of the semiconductor substrate before the depositing the first high-κ material and before the depositing the fill material, wherein the first high-κ material is disposed between the dielectric capping material and the fill material; and
depositing an oxide-based material to cover a top surface of the inter-layer dielectric layer and form a capping layer, wherein the inter-layer dielectric layer is disposed between the front side of the semiconductor substrate and the capping layer.
